(19) United States
(12) Patent Application Publication
(10) Pub. No.: US 2026/0173447 A1
(43) Pub. Date: Jun. 18, 2026

(54) CONTROL CIRCUIT, THIN FILM TRANSISTOR AND MANUFACTURING METHOD THEREOF

(71) Applicant: AUO Corporation, Hsinchu City (TW)

(72) Inventors: Jian-Jie Chen, Hsinchu City (TW); Yen-Hao Chen, Hsinchu City (TW); Wan-Ching Su, Hsinchu City (TW); Cheng-Wei Jiang, Hsinchu City (TW); Jia-Hao Du, Hsinchu City (TW); Yi-Da He, Hsinchu City (TW)

(73) Assignee: AUO Corporation, Hsinchu City (TW)

(21) Appl. No.: 19/235,591

(22) Filed: Jun. 12, 2025

(30) Foreign Application Priority Data
Dec. 13, 2024 (TW) 113148818

(51) Int. Cl. H10D 30/67; H10D 30/01

(52) U.S. Cl. CPC H10D 30/6725; H10D 30/0312; H10D 30/6733

(57) ABSTRACT

A thin film transistor includes a buffer layer, a semiconductor layer, a gate dielectric layer, a first gate electrode, a source, and a drain. The buffer layer is disposed on the substrate. An upper surface of the buffer layer has a first surface, a second surface, a third surface, a fourth surface, and a fifth surface sequentially connected to form a recess. The semiconductor layer is disposed in the recess. The gate dielectric layer is disposed on the substrate, the semiconductor layer, and the buffer layer. The first gate is disposed on the gate dielectric layer and corresponds to the semiconductor layer. The source and the drain are disposed on the substrate and connected to the semiconductor layer. In addition, a manufacturing method of the thin film transistor and a control circuit including the thin film transistor are also provided.

### CROSS-REFERENCE TO RELATED APPLICATION

This application claims the priority benefit of Taiwan application serial no. 113148818, filed on Dec. 13, 2024. The entirety of the above-mentioned patent application is hereby incorporated by reference herein and made a part of this specification.

### BACKGROUND

### Technical Field

The disclosure relates to a control circuit, a thin film transistor, and a manufacturing method thereof.

### Related Art

A thin film transistor is a control element, which may be applied in various control circuits. The thin film transistor includes a gate, a semiconductor layer corresponding to the gate, a gate insulating layer disposed between the gate and the semiconductor layer, and a source and a drain each connected to the semiconductor layer. Generally, to increase a current of the thin film transistor, the gate insulating layer may be thinned, or a gate insulating layer with high dielectric constant may be used. However, while thinning the gate insulating layer or using the gate insulating layer with high dielectric constant, the electric field between the gate and the semiconductor layer may increase, resulting in excessive electric field near the corners of the semiconductor layer, so that the gate insulating layer is prone to deterioration, and the thin film transistor may eventually fail to turn off normally.

### SUMMARY

The disclosure provides a thin film transistor with good performance.

The disclosure provides a control circuit, including a thin film transistor with good performance.

The disclosure provides a manufacturing method of a thin film transistor, which may manufacture a thin film transistor with good performance.

A thin film transistor of the disclosure includes a buffer layer, a semiconductor layer, a gate dielectric layer, a first gate, a source, and a drain. The buffer layer is disposed on a substrate. An upper surface of the buffer layer has a first surface, a second surface, a third surface, a fourth surface, and a fifth surface. The first surface, the second surface, the third surface, the fourth surface, and the fifth surface are sequentially connected to form a recess. The semiconductor layer is disposed in the recess. The gate dielectric layer is disposed on the substrate, the semiconductor layer, and the buffer layer. The first gate is disposed on the gate dielectric layer and corresponds to the semiconductor layer. The source and the drain are disposed on the substrate and connected to the semiconductor layer.

A control circuit of the disclosure includes multiple control elements. At least one of the control elements includes the aforementioned thin film transistor.

A manufacturing method of a thin film transistor of the disclosure includes the following steps. A buffer layer is formed on a substrate, where an upper surface of the buffer layer has a first surface, a second surface, a third surface, a fourth surface, and a fifth surface, and the first surface, the second surface, the third surface, the fourth surface and the fifth surface are sequentially connected to form a recess. A semiconductor material layer is formed on the buffer layer, where the semiconductor material layer includes a first part and a second part connected to the first part, the first part of the semiconductor material layer is disposed on the second surface, the third surface and the fourth surface of the buffer layer, and the second part of the semiconductor material layer is disposed on the first surface and the fifth surface of the buffer layer. The second part of the semiconductor material layer is removed while the first part of the semiconductor material layer is preserved to form a semiconductor layer. A gate dielectric layer is formed on the buffer layer and the semiconductor layer. A first gate is formed on the gate dielectric layer. A source and a drain are formed on the substrate, where the source and the drain are connected to the semiconductor layer.

### BRIEF DESCRIPTION OF THE DRAWINGS

FIG. 1A to FIG. 1G are cross-sectional schematic views of a manufacturing process of a thin film transistor according to an embodiment of the disclosure.

FIG. 2 is a cross-sectional schematic view of a thin film transistor according to an embodiment of the disclosure.

FIG. 3A to FIG. 3D are cross-sectional schematic views of a manufacturing process of a thin film transistor according to another embodiment of the disclosure.

FIG. 4A to FIG. 4D are cross-sectional schematic views of a manufacturing process of a thin film transistor according to yet another embodiment of the disclosure.

FIG. 5 is a three-dimensional schematic view of a material layer of a thin film transistor according to yet another embodiment of the disclosure.

FIG. 6 is an equivalent circuit schematic view of a control circuit according to an embodiment of the disclosure.

### DESCRIPTION OF THE EMBODIMENTS

Reference is now made in detail to exemplary embodiments of the disclosure, examples of which are illustrated in the accompanying drawings. Wherever possible, the same reference numerals are used in the drawings and descriptions to refer to the same or similar parts.

It should be understood that when an element such as a layer, a film, a region, or a substrate is referred to as being “on” or “connected to” another element, it may be directly on or connected to the other element, or intervening elements may also be present. In contrast, when an element is referred to as being “directly on” or “directly connected to” another element, no intervening elements are present. As used herein, “connected” may refer to physical and/or electrical connection. Furthermore, “electrical connection” or “coupling” may be another element between two elements.

Considering the particular amount of measurement and measurement-related errors discussed (i.e., the limitations of the measurement system), the terminology “about,” “approximately,” “essentially,” or “substantially” used herein includes the average of the stated value and an acceptable range of deviations from the particular value as determined by those skilled in the art. For instance, the terminology “about” may refer to as being within one or more standard deviations of the stated value, or within ±30%, ±20%, ±10%, or ±5%. Furthermore, the terminology “about,” “approximately,” “essentially,” or “substantially” as used herein may be chosen from a range of acceptable deviations or standard deviations depending on the optical properties, etching properties, or other properties, rather than one standard deviation for all properties.

Unless otherwise defined, all terms (including technical and scientific terms) used herein have the same meaning as commonly understood by one of ordinary skill in the art to which this invention belongs. It should be further understood that terms, such as those defined in commonly used dictionaries, should be interpreted as having a meaning that is consistent with their meaning in the context of the relevant art and the disclosure, and should not be interpreted in an idealized or overly formal sense unless expressly so defined herein.

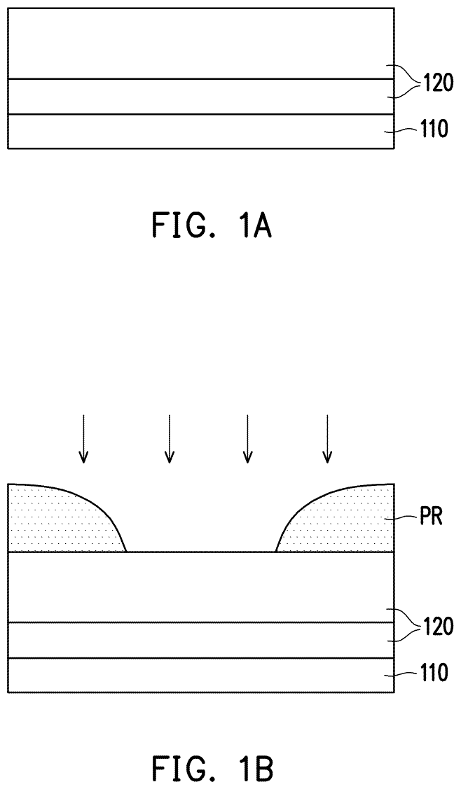

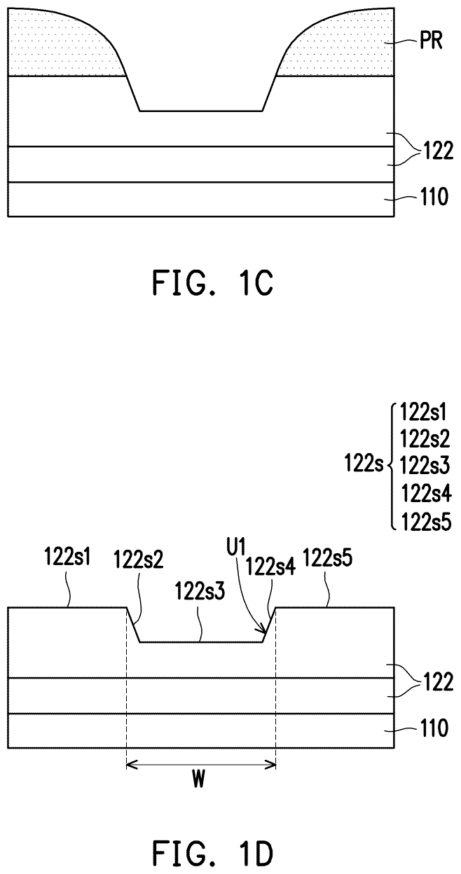

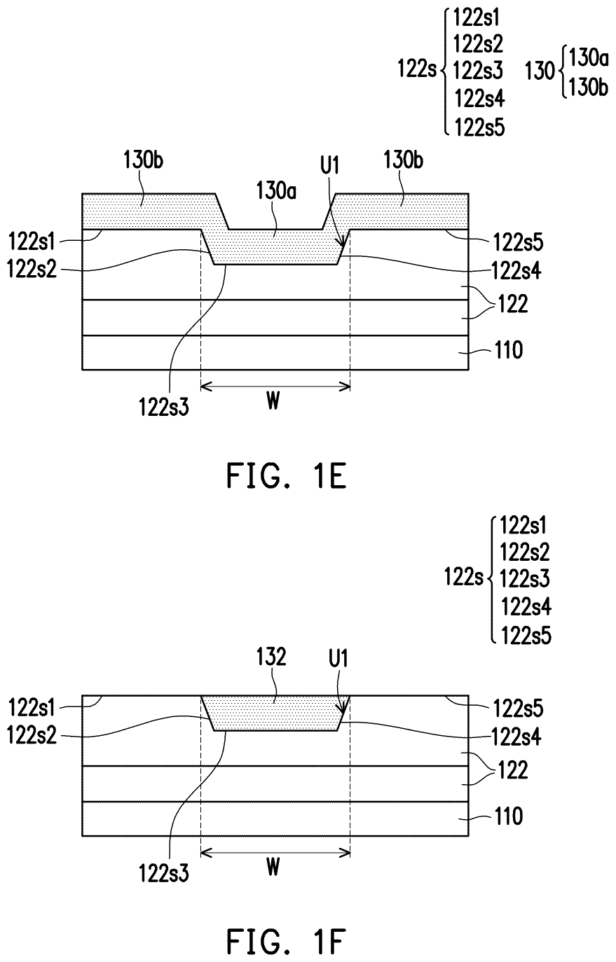

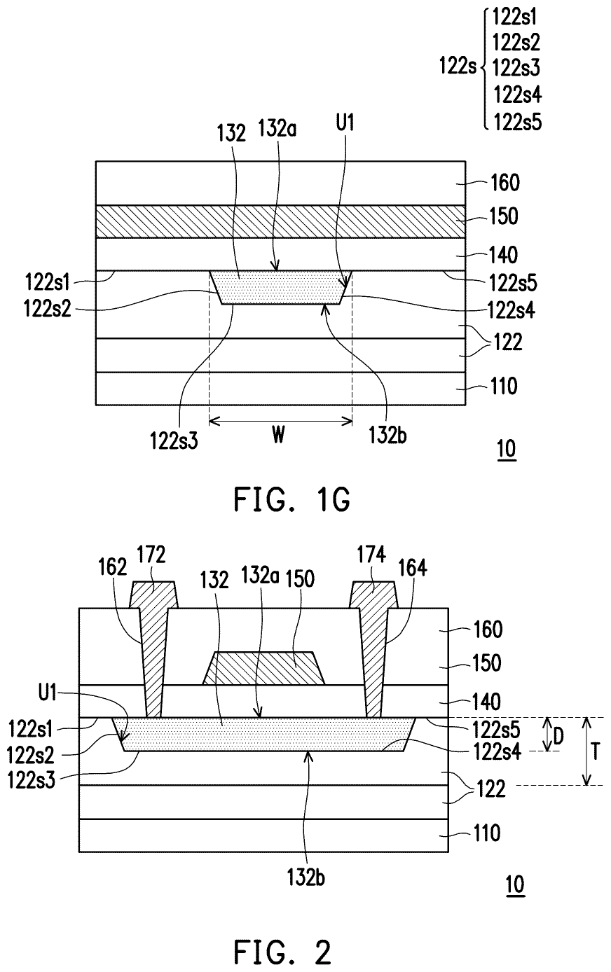

FIG. 1A to FIG. 1G are cross-sectional schematic views of a manufacturing process of a thin film transistor according to an embodiment of the disclosure. Referring to FIG. 1A to FIG. 1D, first, a buffer layer 122 (marked in FIG. 1D) is formed on a substrate 110. Referring to FIG. 1D, an upper surface 122 s of the buffer layer 122 has a first surface 122s1, a second surface 122s2, a third surface 122s3, a fourth surface 122s4, and a fifth surface 122s5. The first surface 122s1, the second surface 122s2, the third surface 122s3, the fourth surface 122s4, and the fifth surface 122s5 are sequentially connected to form a recess U1.

In some embodiments, for example, referring to FIG. 1A, a buffer material layer 120 may first be formed on the substrate 110. Referring to FIG. 1B, a photoresist PR is then formed on the buffer material layer 120. Subsequently, referring to FIG. 1B and FIG. 1C, and using the photoresist PR as a mask, the buffer material layer 120 is patterned to form a buffer layer 122 having a recess U1. Finally, referring to FIG. 1C and FIG. 1D, the photoresist PR on the buffer layer 122 is removed. However, the disclosure is not limited to thereto. In other embodiments, other methods may be used to form the buffer layer 122 having the recess U1.

In some embodiments, referring to FIG. 1D, a material of the substrate 110 may be glass, quartz, organic polymer, opaque/reflective materials (for example, conductive materials, wafer, ceramic, or other applicable materials), or other applicable materials. In some embodiments, the buffer layer 122 may be a single layer structure or a multi-layer structure. In some embodiments, a material of the buffer layer 122 may be an inorganic material (for example, silicon oxide, silicon nitride, silicon oxynitride, or a stacking layer of at least two of the aforementioned materials), an organic material, or a combination thereof. In some embodiments, the recess U1 has a bottom area near the substrate 110 and a top area away from the substrate 110, where the top area is greater than the bottom area. In some embodiments, a width W of the recess U1 may gradually increase when moving away from the substrate 110.

Next, referring to FIG. 1E, a semiconductor material layer 130 is formed on the buffer layer 122. The semiconductor material layer 130 includes a first part 130a and a second part 130b connected to the first part 130a. The first part 130a of the semiconductor material layer 130 is disposed on the second surface 122s2, the third surface 122s3, and the fourth surface 122s4 of the buffer layer 122. That is, the first part 130a of the semiconductor material layer 130 is disposed in the recess U1 of the buffer layer 122. The second part 130b of the semiconductor material layer 130 is disposed on the first surface 122s1 and the fifth surface 122s5 of the buffer layer 122. That is, the second part 130b of the semiconductor material layer 130 is disposed on other regions of the upper surface 122s outside the recess U1.

Next, referring to FIG. 1E and FIG. 1F, the second part 130b of the semiconductor material layer 130 is removed while the first part 130a of the semiconductor material layer 130 is preserved to form a semiconductor layer 132. The semiconductor layer 132 is disposed in the recess U1 of the buffer layer 122. In some embodiments, the semiconductor layer 132 may fill up the recess U1 of the buffer layer 122. For example, in some embodiments, the second part 130b of the semiconductor material layer 130 may be removed by using chemical mechanical polishing (CMP). In some embodiments, during a process of CMP, the substrate 110, the buffer layer 122 on the substrate 110, and the semiconductor material layer 130 on the buffer layer 122 may be placed on a rotating table (not shown), and then a polishing head (not shown) is configured to grind the semiconductor material layer 130 on the rotating table. During a process of grinding, a slurry is added. In some embodiments, the rotation speed of the rotating table below may be 20 rpm. The rotation speed of the polishing head above may be 30 rpm. The pressure applied by the polishing head to the semiconductor material layer 130 may be 0.47 psi. The time of grinding may be 150 sec. The slurry may include water and multiple silicon dioxide particles mixed in the water, where a weight percentage of water may be greater than 51%, a weight percentage of the silicon dioxide particles may be less than 49%, and the particle size of the silicon dioxide particles may be 35 nm, but the disclosure is not limited thereto.

In some embodiments, referring to FIG. 1F, a material of the semiconductor layer 132 may be a silicon-containing semiconductor material, such as but not limited to polysilicon, microcrystalline silicon, single crystal silicon, amorphous silicon, or silicon-rich dielectric materials. With polysilicon as a preferred example, the semiconductor layer 132 has a channel region (not marked) between two heavily doped regions (not marked). In other embodiments, a lightly doped region (not marked) may be located between the channel region and a heavily doped region. That is, the lightly doped region and the heavily doped region may be disposed on either side of the channel region. In an embodiment, the heavily doped region and an extension region (not marked) may be disposed on one side of the channel region, while the lightly doped region and the heavily doped region may be disposed on another side of the channel region.

Next, referring to FIG. 1G, a gate dielectric layer 140 is formed on the buffer layer 122 and the semiconductor layer 132. The gate dielectric layer 140 is disposed on the substrate 110, the semiconductor layer 132, and the buffer layer 122. In some embodiments, the gate dielectric layer 140 may cover the semiconductor layer 132 and the buffer layer 122 in a planar manner, but the disclosure is not limited thereto. In some embodiments, a material of the gate dielectric layer 140 may be an inorganic material (for example, silicon oxide, silicon nitride, silicon oxynitride, or a stacking layer of at least two of the aforementioned materials), an organic material, or a combination thereof.

Next, referring to FIG. 1G, a first gate 150 is formed on the gate dielectric layer 140. The first gate 150 is disposed on the gate dielectric layer 140 and corresponds to the semiconductor layer 132. The gate dielectric layer 140 is located between the first gate 150 and the semiconductor layer 132 as well as between the first gate 150 and the buffer layer 122. In some embodiments, based on conductivity considerations, the first gate 150 generally uses a metal material. However, the disclosure is not limited thereto. According to other embodiments, the first gate 150 may also use other conductive materials, for example, alloys, nitrides of metal material, oxides of metal material, oxynitrides of metal material, or stacking layers of metal material, and other conductive materials.

FIG. 2 is a cross-sectional schematic view of a thin film transistor according to an embodiment of the disclosure. FIG. 1G shows a cross-section of a thin film transistor 10 in a width direction thereof. FIG. 2 shows a cross-section of the thin film transistor 10 in a length direction thereof. Next, in some embodiments, referring to FIG. 1G and FIG. 2, an interlayer dielectric layer 160 may be formed to cover the gate dielectric layer 140 and the first gate 150, where the interlayer dielectric layer 160 has multiple openings 162 and 164. In some embodiments, a material of the interlayer dielectric layer 160 may be an inorganic material (for example, silicon oxide, silicon nitride, silicon oxynitride, or stacking layers of at least two of the aforementioned materials), an organic material, or a combination thereof.

Next, referring to FIG. 2, a source 172 and a drain 174 are formed on the substrate 110, where the source 172 and the drain 174 are disposed on the substrate 110 and connected to the semiconductor layer 132. In some embodiments, the source 172 and the drain 174 may be formed on the interlayer dielectric layer 160, the source 172 and the drain 174 are disposed on the interlayer dielectric layer 160, and the source 172 and the drain 174 are connected to the semiconductor layer 132 via the openings 162 and 164 of the interlayer dielectric layer 160. Therefore, the thin film transistor 10 is completed.

Referring to FIG. 1G and FIG. 2, it is worth noting that the semiconductor layer 132 of the thin film transistor 10 is disposed in the recess U1 of the buffer layer 122. Thereby, generating an excessively strong edge electric field between the semiconductor layer 132 and the first gate 150 may be avoided, so as to achieve an effect of eliminating an edge electric field. In some embodiments, an area of the top surface 132a of the semiconductor layer 132 away from the substrate 110 is greater than an area of the bottom surface 132b of the semiconductor layer 132 close to the substrate 110. In some embodiments, referring to FIG. 2, a depth D (marked in FIG. 2) of the recess U1 substantially falls within a range of 15% to 45% of a thickness T (marked in FIG. 2) of the buffer layer 122.

It should be noted that reference numerals of the elements and a part of contents of the aforementioned embodiment are also used in the following embodiment, where the same reference numerals denote the same or like elements, and descriptions of the same technical contents are omitted. The aforementioned embodiment may be referred for descriptions of the omitted parts, and detailed descriptions thereof are not repeated in the following embodiment.

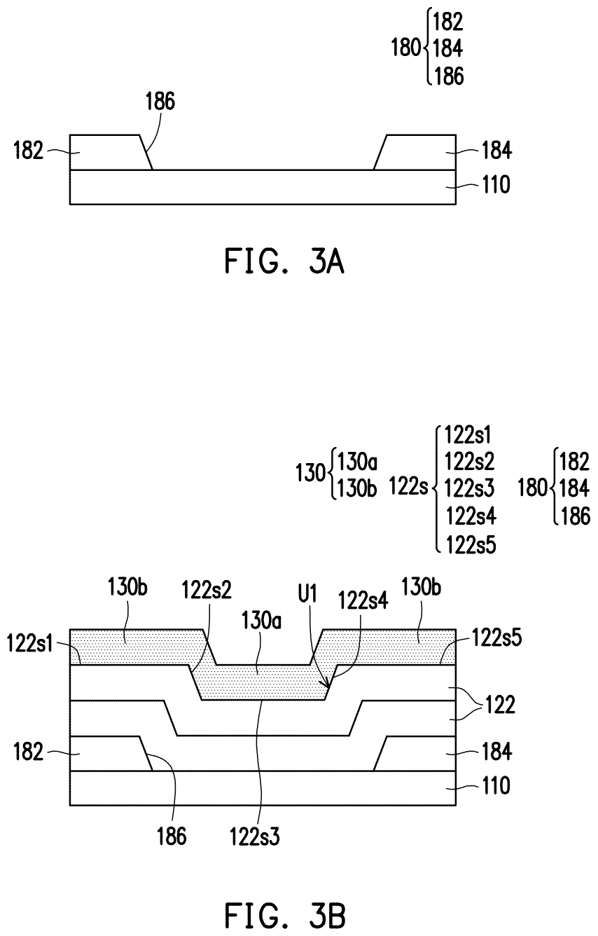

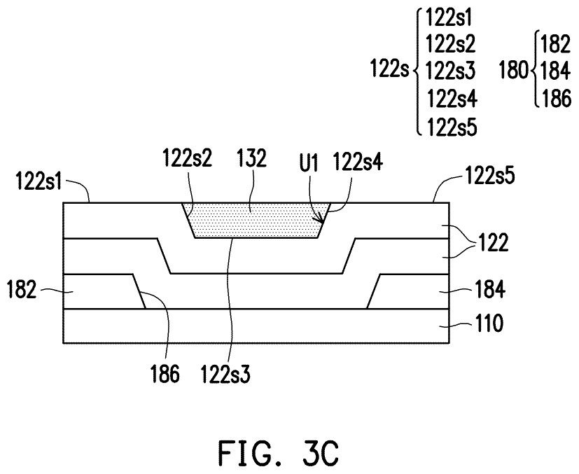

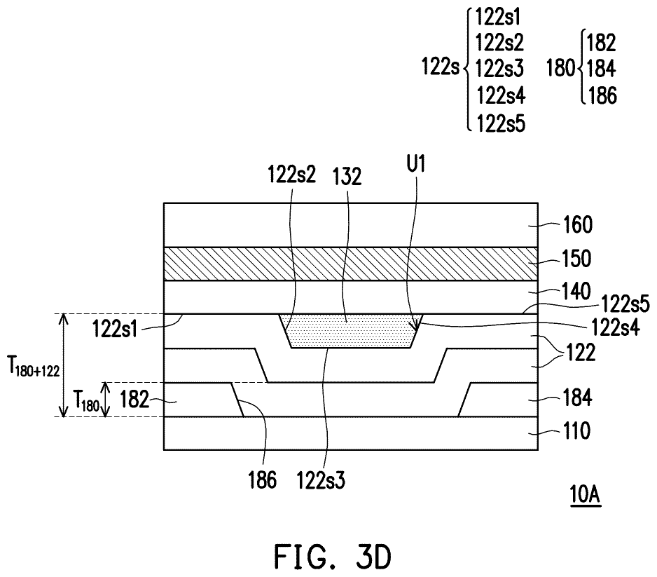

FIG. 3A to FIG. 3D are cross-sectional schematic views of a manufacturing process of a thin film transistor according to another embodiment of the disclosure. A manufacturing process of a thin film transistor 10A in FIG. 3A to FIG. 3D is similar to the manufacturing process of the thin film transistor 10 in FIG. 1A to FIG. 1G. The difference between the two lies in that the formation method of the recess U1 of the buffer layer 122 of the thin film transistor 10A is different from the formation method of the recess U1 of the buffer layer 122 of the thin film transistor 10.

Specifically, in this embodiment, referring to FIG. 3A and FIG. 3B and before forming the buffer layer 122, a material layer 180 may first be formed on the substrate 110, where the material layer 180 has an opening 186, a first part 182, and a second part 184, and the opening 186 of the material layer 180 separates the first part 182 and the second part 184 of the material layer 180. In some embodiments, the material layer 180 may be a single-layer structure or a multi-layer structure, and a material of the material layer 180 may be an organic material, an inorganic material, a conductive material, or a semiconductor material. The material layer 180 may be a single-layer structure or a multi-layer structure. Multiple film layers of the multi-layer structure may use the same material or different materials.

Next, referring to FIG. 3B, the buffer layer 122 is conformally formed on the material layer 180. The material layer 180 is disposed on the substrate 110, and is located between the buffer layer 122 and the substrate 110. The first part 182 and the second part 184 of the material layer 180 respectively correspond to and overlap with the first surface 122s1 and the fifth surface 122s5 of the buffer layer 122. The recess U1 of the buffer layer 122 is formed due to a part of the buffer layer 122 sinking into the opening 186 of the material layer 180. Therefore, the recess U1 of the buffer layer 122 corresponds to the opening 186 of the material layer 180. That is, a position of the opening 186 of the material layer 180 overlaps with a position of the recess U1 of the buffer layer 122.

In some embodiments, referring to FIG. 3D, the recess U1 of the buffer layer 122 may be located within an area of the opening 186 of the material layer 180. In some embodiments, a thickness T180 of any one of the first part 182 and the second part 184 of the material layer 180 may fall within a range of 7% to 25% of a sum of a thickness T₁₈₀₊₁₂₂ of the buffer layer 122 and any one of the first part 182 and the second part 184 of the material layer 180, but the disclosure is not limited thereto.

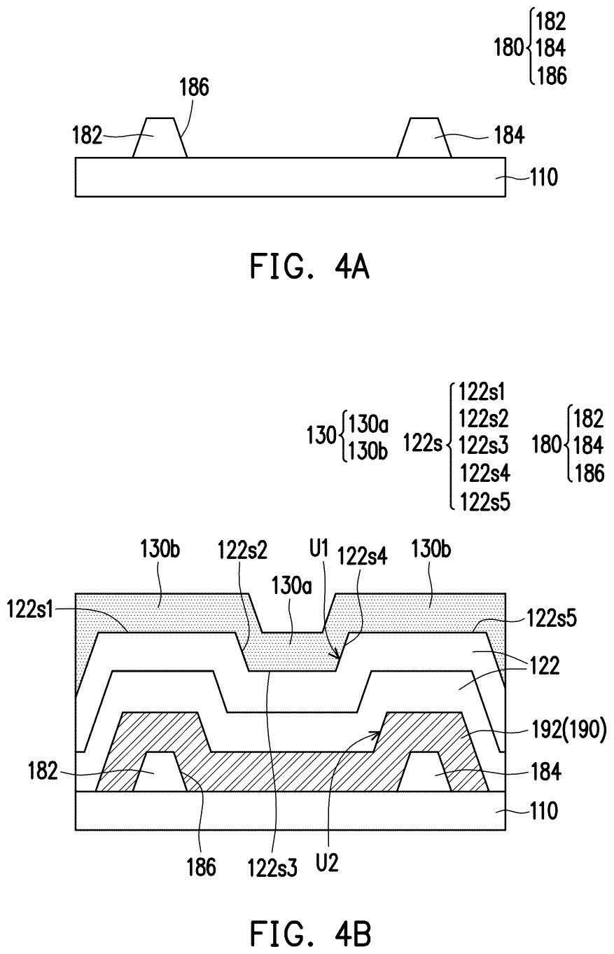

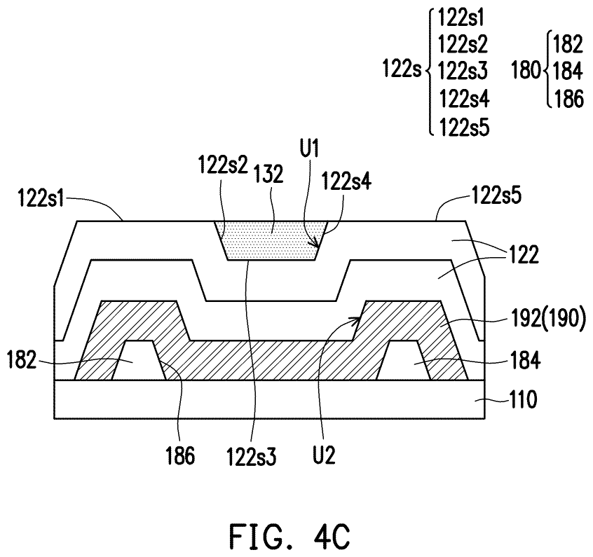

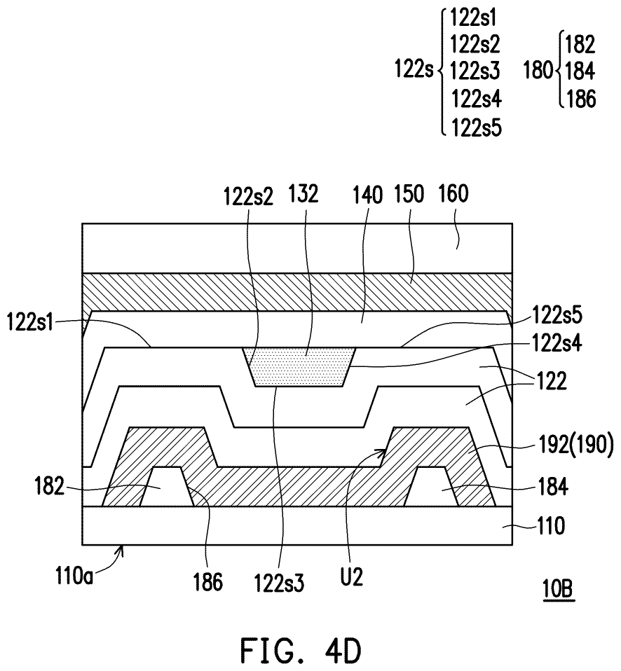

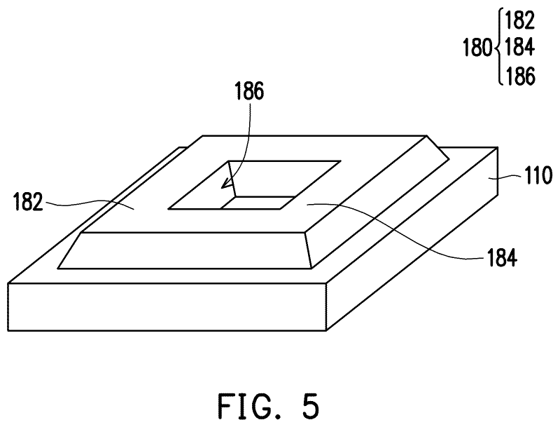

FIG. 4A to FIG. 4D are cross-sectional schematic views of a manufacturing process of a thin film transistor according to yet another embodiment of the disclosure. A manufacturing process of a thin film transistor 10B in FIG. 4A to FIG. 4D is similar to the manufacturing process of the thin film transistor 10A in FIG. 3A to FIG. 3D, and the differences between the two are as follows. The manufacturing process of the thin film transistor 10B in FIG. 4A to FIG. 4D further includes: after forming the material layer 180 and before forming the buffer layer 122, a conductive layer 190 is conformally formed on the material layer 180. The conductive layer 190 covers the first part 182 and the second part 184 of the material layer 180 and a part of the substrate 110 located between the first part 182 and the second part 184 of the material layer 180. A part of the conductive layer 190 fills into the opening 186 of the material layer 180 and has a recess U2. The recess U2 of the conductive layer 190 and the recess U1 of the buffer layer 122 correspond to the opening 186 of the material layer 180. A position of the recess U2 of the conductive layer 190, the position of the recess U1 of the buffer layer 122, and the position of the opening 186 of the material layer 180 overlap with each other. FIG. 5 is a three-dimensional schematic view of a material layer of a thin film transistor according to yet another embodiment of the disclosure. In some embodiments, referring to FIG. 4D and FIG. 5, the material layer 180 may selectively be in a ring shape to define a closed opening 186.

In some embodiments, referring to FIG. 4D, the conductive layer 190 may include a second gate 192. In some embodiments, the thin film transistor 10B includes a first gate 150 and a second gate 192, to become a dual-gate thin film transistor, but the disclosure is not limited thereto. In some embodiments, the conductive layer 190 may be a single-layer structure or a multi-layer structure. In some embodiments, a material of the conductive layer 190 may be a transparent material or a reflective material. If the conductive layer 190 is a multi-layer structure, multiple layers of the conductive layer 190 may use the same material or different materials. If the conductive layer 190 includes a reflective material or a stack of reflective material and a transparent material, the conductive layer 190, in addition to serving as the second gate 192, may also serve as a light-shielding layer to block light entering the semiconductor layer 132 from the outer surface 110a of the substrate 110.

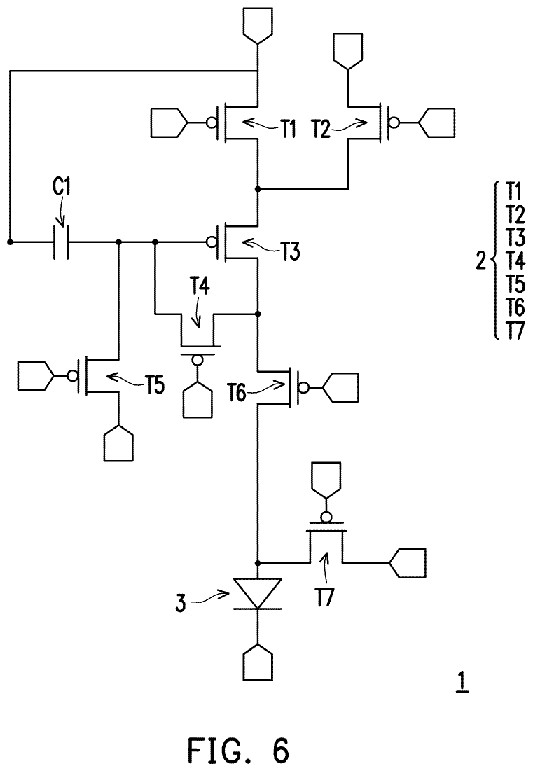

FIG. 6 is an equivalent circuit schematic view of a control circuit according to an embodiment of the disclosure. Referring to FIG. 6, a control circuit 1 includes multiple control elements 2. At least one control element 2 may be the aforementioned thin film transistors 10, 10A, or 10B. In some embodiments, the control circuit 1 may be a pixel control circuit, where at least one control element 2 of the pixel control circuit is electrically connected to a pixel element 3. The at least one control element 2 electrically connected to the pixel element 3 may be referred to as a driving element, a light-emitting control element, or other elements. In some embodiments, the pixel element 3 may be an inorganic self-emitting element, an organic self-emitting element, a non-self-emitting element, or other suitable pixel elements.

In some embodiments, the pixel control circuit is, for example, a 7T1C architecture as shown in FIG. 6. The 7T1C architecture includes seven thin film transistors T1, T2, T3, T4, T5, T6, T7, and a capacitor C1. The control elements 2 of the control circuit 1 may include seven thin film transistors T1, T2, T3, T4, T5, T6, T7, where at least one of the thin film transistors T1, T2, T3, T4, T5, T6, T7 may be the aforementioned thin film transistors 10, 10A, or 10B. However, the disclosure is not limited thereto. If the control circuit 1 is a pixel control circuit, the architecture of the pixel control circuit is not limited to the 7T1C architecture shown in FIG. 6. In other embodiments, if the control circuit 1 is a pixel control circuit, the pixel control circuit may also be a 1T1C architecture, a 2T1C architecture, a 3T1C architecture, a 3T2C architecture, a 4T1C architecture, a 4T2C architecture, a 5T1C architecture, a 5T2C architecture, a 6T2C architecture, a 7T2C architecture, or any possible architecture. Furthermore, the disclosure does not limit the control circuit 1 to necessarily be a pixel control circuit. In other embodiments, the control circuit 1 may also be other types of circuits, such as but not limited to a gate control circuit or a data control circuit.

What is claimed is:

1. A thin film transistor, comprising:
a buffer layer, disposed on a substrate, wherein an upper surface of the buffer layer has a first surface, a second surface, a third surface, a fourth surface, and a fifth surface, and the first surface, the second surface, the third surface, the fourth surface, and the fifth surface are sequentially connected to form a recess;
a semiconductor layer, disposed in the recess;
a gate dielectric layer, disposed on the substrate, the semiconductor layer, and the buffer layer;
a first gate, disposed on the gate dielectric layer and corresponding to the semiconductor layer;
a source and a drain, disposed on the substrate and connected to the semiconductor layer.

2. The thin film transistor according to claim 1, wherein a depth of the recess substantially falls within a range of 15% to 45% of a thickness of the buffer layer.

3. The thin film transistor according to claim 1, further comprising:
a material layer, disposed on the substrate, and located between the buffer layer and the substrate, wherein the material layer has an opening, a first part, and a second part, the opening of the material layer separates the first part and the second part of the material layer, the first part and the second part of the material layer respectively correspond to and overlap with the first surface and the fifth surface of the buffer layer, and the opening of the material layer corresponds to the recess of the buffer layer.

4. The thin film transistor according to claim 3, wherein the recess of the buffer layer is located within an area of the opening of the material layer.

5. The thin film transistor according to claim 3, wherein a thickness of any one of the first part and the second part of the material layer falls within a range of 7% to 25% of a sum of a thickness of the buffer layer and any one of the first part and the second part of the material layer.

6. The thin film transistor according to claim 3, further comprising:
a conductive layer, disposed on the substrate, wherein the conductive layer covers the first part and the second part of the material layer and a part of the substrate located between the first part and the second part of the material layer.

7. The thin film transistor according to claim 6, wherein the conductive layer comprises a second gate.

8. The thin film transistor according to claim 1, further comprising:
an interlayer dielectric layer, disposed on and covering the substrate, the gate dielectric layer, and the first gate, wherein the interlayer dielectric layer has a plurality of openings, the source and the drain are disposed on the interlayer dielectric layer, and the source and the drain are connected to the semiconductor layer via the plurality of openings.

9. A control circuit, comprising:
a plurality of control elements, wherein at least one of the plurality of control elements comprises the thin film transistor according to claim 1.

10. The control circuit according to claim 9, wherein the control circuit comprises at least one of a pixel control circuit, a gate control circuit, and a data control circuit.

11. A manufacturing method of a thin film transistor, comprising:
forming a buffer layer on a substrate, wherein an upper surface of the buffer layer has a first surface, a second surface, a third surface, a fourth surface, and a fifth surface, and the first surface, the second surface, the third surface, the fourth surface, and the fifth surface are sequentially connected to form a recess;
forming a semiconductor material layer on the buffer layer, wherein the semiconductor material layer comprises a first part and a second part connected to the first part, the first part of the semiconductor material layer is disposed on the second surface, the third surface, and the fourth surface of the buffer layer, and the second part of the semiconductor material layer is disposed on the first surface and the fifth surface of the buffer layer;
removing the second part of the semiconductor material layer while preserving the first part of the semiconductor material layer to form a semiconductor layer;
forming a gate dielectric layer on the buffer layer and the semiconductor layer;
forming a first gate on the gate dielectric layer; and
forming a source and a drain on the substrate, wherein the source and the drain are connected to the semiconductor layer.

12. The manufacturing method of the thin film transistor according to claim 11, wherein a depth of the recess substantially falls within a range of 15% to 45% of a thickness of the buffer layer.

13. The manufacturing method of the thin film transistor according to claim 11, further comprising:
before forming the buffer layer, forming a material layer on the substrate, wherein the material layer has an opening, a first part, and a second part, and the opening of the material layer separates the first part and the second part of the material layer; and
the step of forming the buffer layer on the substrate comprises: conformally forming the buffer layer on the material layer, wherein the first part and the second part of the material layer respectively correspond to and overlap with the first surface and the fifth surface of the buffer layer, and the opening of the material layer corresponds to the recess of the buffer layer.

14. The manufacturing method of the thin film transistor according to claim 13, wherein the recess of the buffer layer is located within an area of the opening of the material layer.

15. The manufacturing method of the thin film transistor according to claim 13, wherein a thickness of any one of the first part and the second part of the material layer falls within a range of 7% to 25% of a sum of a thickness of the buffer layer and any one of the first part and the second part of the material layer.

16. The manufacturing method of the thin film transistor according to claim 13, further comprising:
after forming the material layer and before forming the buffer layer, conformally forming a conductive layer on the material layer.

17. The manufacturing method of the thin film transistor according to claim 16, wherein the conductive layer comprises a second gate.

18. The manufacturing method of the thin film transistor according to claim 11, further comprising:
forming an interlayer dielectric layer to cover the gate dielectric layer and the first gate, wherein the interlayer dielectric layer has a plurality of openings, the source and the drain are disposed on the interlayer dielectric layer, and the source and the drain are connected to the semiconductor layer via the plurality of openings.
